(19) United States
(12) Patent Application Publication
(10) Pub. No.: US 2025/0374440 A1
(43) Pub. Date: Dec. 4, 2025

(54) Method for forming an electrical and mechanical connection arrangement of at least two flexible printed circuit boards (flexible PCB) or flexible PCB segments as well as subsequently manufactured flexible PCB of any length

(71) Applicants: FEW Fahrzeugelektrik Werk GmbH & Co. KG, Zwenkau (DE); FEW Automotive FPC Application Co., Ltd, Shenzhen (CN)

(72) Inventors: Xiongbin Gu, Shenzhen (CN); Peter Thomas Krabs, Leipzig (DE); Andreas Knoll, Oelsnitz (DE); Ying Leibnitz, Leipzig (DE)

(73) Assignees: FEW Fahrzeugelektrik Werk GmbH & Co. KG, Zwenkau (DE); FEW Automotive FPC Application Co., Ltd, Shenzhen (CN)

(21) Appl. No.: 19/221,026

(22) Filed: May 28, 2025

(30) Foreign Application Priority Data
Jun. 3, 2024 (CN) 2024107109935

(51) Int. Cl. H05K 3/36; H05K 1/14

(52) U.S. Cl. CPC H05K 3/361; H05K 1/147; H05K 2201/058

(57) ABSTRACT

The invention relates to a method for forming an electrical and mechanical connection arrangement of at least two flexible PCBs or flexible PCB segments, each consisting of a composite of a base insulating layer, an electrically conductive structure, in particular conducting tracks, and a cover insulating layer. The top insulating layer is exposed or removed in a section of the connection area in order to obtain contact surfaces. Using reinforcement and positioning layers and after correct positioning by means of positioning marks, a joining and laminating step is carried out in order to achieve a secure and flexible connection.

The invention relates to a method for forming an electrical and mechanical connection arrangement of at least two flexible PCBs or flexible PCB segments, whereby these each consist of a composite of a base insulating layers, an electrically conductive structure, in particular conducting tracks, and a cover insulating layer and the cover insulating layer is exposed or removed in a section of the connection region in order to obtain contact surfaces in accordance with the general term of claim 1 as well as a flexible PCB of any length in accordance with the features of claim 13.

Flexible PCBs are used as connecting elements in electrical circuits but can also comprise electrical circuits in their own right if active and/or passive electronic components are also integrated.

The advantage of flexible PCBs is that they can be bent, wrapped, folded, and thus laid in almost any direction because of their non-rigid design and their low thickness in the Z direction. This allows flexible PCBs to be inserted into housing structures and make electrical connections in a similar way to a stranded conductor. Another advantage is the low weight of flexible PCBs. They are thus preferred for use in assemblies with high integration density such as in mobile electronic components, communication devices, and computer peripherals as well as other applications (e.g., in automotive engineering and aerospace).

The flexibility of flexible PCBs also allows for simplified assembly, in particular because of the possibility of compensating for installation tolerances on the device side.

Flexible PCBs essentially consist of a base layer of insulating carrier material, one or more electrical conductors, and a top layer (also made of an insulating material).

The aforementioned layers are firmly bonded together by lamination.

For contacting purposes, the ends of the electrical conductors are exposed through openings in the base and/or cover layer in order to make the necessary electrical contact with other electrical or electronic components. Such a contact can be made by soldering as well as by conductive adhesive, crimping, or riveting.

The production of flexible PCBs is usually based on two different technologies.

Laminating in sheets is well known. Here, the individual conductors are arranged on sheets in the plane and, if necessary, nested so that a certain number of individual flexible PCBs can be laminated in a single step.

The individual PCBs or PCB segments are then separated from each other by punching or plotting using a cutting knife or laser.

In this process, the limiting element for the length (x) and the width (y) of the flexible PCBs is the area of the laminating press available.

The surfaces of laminating presses are limited. Special machines with correspondingly higher costs would therefore have to be used to manufacture larger PCBs with larger dimensions.

Another well-known method is roll-to-roll lamination.

In this process, the flexible PCBs are produced on continuous rolls or laminated in sections. This allows flexible PCBs with a greater length (x) to be produced. However, the limiting element here is the width (y) because the rolls are essentially limited to a width of 250-500 mm.

In order to be able to connect individual circuit boards to each other or realize angular structures of flexible circuit boards, it is state of the art to connect individual segments both electrically and mechanically. This connection can be made using a conductive adhesive, for example. To protect the conductive adhesive connection, the connection area is usually protected by a rigid element (e.g., in the form of a plastic encapsulation).

EP 3 610 707 B1 also discloses a multilayer structure with electrical contacting of a flexible substrate film with conductive structures (e.g., flexible PCBs). In this solution, the actual substrate film is thermoformable and encapsulated with a plastic layer. Electrical contact is made by means of a contact element, which is guided through an opening in the substrate film.

EP 3 331 114 B1 discloses a connection system for flat cables with a connection box in which the flat cable ends to be connected are fixed.

According to EP 2 440 024 B1, non-conductive adhesives, conductive adhesives, and solder are used in the connection process for the contacts of flexible PCBs. In particular, a bonding process is used for reliable electrical contacting.

When joining flexible PCBs with filler materials (e.g., as known from WO 2010/140469 A), the connection loses the character of flexibility at its joining point; this limits, if not renders impossible, the advantages of flexible PCBs with regard to the applications described above.

From the foregoing, it is therefore the purpose of the invention to provide a further developed method for forming an electrical and mechanical connection of at least two flexible PCBs; this allows dimensions to be freely selected in length and width (i.e., in one plane), whereby conventional laminating processes with existing laminating presses can be used. A further purpose of the invention is to keep the joint in particular (i.e., the connection area) just as flexible as is specified by the properties of the flexibility of the PCB as such. This means that the connecting area is not rigid but rather flexible and has a lower thickness or height.

The purpose of the invention is solved by a method in accordance with the principle according to claim 1 as well as with a flexible PCB of any length and with a predetermined width in accordance with the combination of features according to claim 13, whereby the sub-claims comprise at least useful embodiments and further embodiments.

The process is based on an electrical and mechanical connection arrangement of at least two flexible PCBs or flexible PCB segments.

The flexible PCB or flexible PCB segments each consist of a composite of a base insulating layer, an electrically conductive structure, in particular comprising conducting tracks and a top insulating layer.

In the area of the actual electrical connection, the cover insulating layer is exposed or removed in order to obtain contact surfaces that are accessible for contacting. The conducting track material can be either copper or aluminum or corresponding alloys. Conducting tracks made of a copper material with corresponding ductility are preferred.

According to the invention, a first flexible PCB with an exposed contact surface is provided with a first reinforcing and positioning layer, and a second flexible PCB with an exposed contact surface is provided with a second reinforcing and positioning layer.

The surface expansions of the first and second reinforcing and positioning layers extend beyond the respective contact surfaces on the back and form the connection area.

Positioning marks, in particular positioning holes, are formed in the reinforcing and positioning layers in order to ensure correct positioning.

A thermally activatable layer or film is then applied or arranged in the connection area, thereby leaving the contact surface areas exposed.

Once the PCBs and their contact surfaces have been positioned correctly, they are joined and laminated.

Lamination is preferably realized in the form of a combined pressure-temperature treatment regime. Lateral protrusions of the reinforcing and positioning layers can then be removed for better handling.

In one embodiment of the invention, the thermally activatable film also has positioning marks—in particular positioning holes—as well as additional recesses in the area corresponding to the exposed contact surfaces. The recess ensures that the contact surfaces facing each other during the lamination process come into direct contact, thereby creating a low-resistance contact connection.

The tolerances with regard to the positional accuracy of the thermally activatable layer or film and the first and second reinforcing and positioning layers are 0.2-0.5 mm.

The diameter of the positioning holes is between 0.5 and 5.0 mm (preferably between 0.5 and 1.5 mm).

In addition, the positioning holes can be used to vent the joint area during the lamination step so that the structure in the joint area is as flat as possible and free of air pockets.

To maintain the desired flexibility in the connection area, both the reinforcing and positioning layers and the thermally activated layer or film are made of a flexible, non-rigid material. The material thickness in the connection area is only slightly greater than the thickness or material thickness of the adjacent flexible conductors and is 100-400 μm.

The positioning marks or positioning holes in the reinforcing and positioning layers consist of a first and a second group.

The spacing in the first group is matched to the dimensions of the contact surfaces as well as to the width of the flexible PCB strips to be connected.

The second group is located both inside and outside of the area occupied by the flexible PCB strips. If the conducting tracks are spaced further apart on the respective PCB and there are corresponding free spaces, the positioning holes can also be located inside the PCB strips.

The reinforcing and positioning layers are preferably made of a thermosetting material; this can also be provided with an adhesive coating.

The thermally activated vision panel or film is preferably made of an epoxy resin material.

The circuit boards or circuit board segments to be connected can include an angle of 0 to 180° (preferably between 90° and 180°).

Also according to the invention is a flexible PCB of any length and with a predetermined width, comprising at least two to n PCB segments and at least one laminate connection arrangement for electrical and mechanical coupling.

The connection arrangement has exposed electrical contact surfaces, which are in direct contact with each other. In addition, there is at least one reinforcing and positioning layer on the top and one on the bottom.

In a further development of the invention, the laminate connection arrangement has an additional layer of a thermally activatable material, in particular an epoxy resin, outside the contact surfaces and surrounding them. This layer also acts as a height equalizer and prevents unwanted stepping in the area of the connection arrangement.

The invention will be explained in more detail below with reference to a design example and with the aid of figures.

Show here:

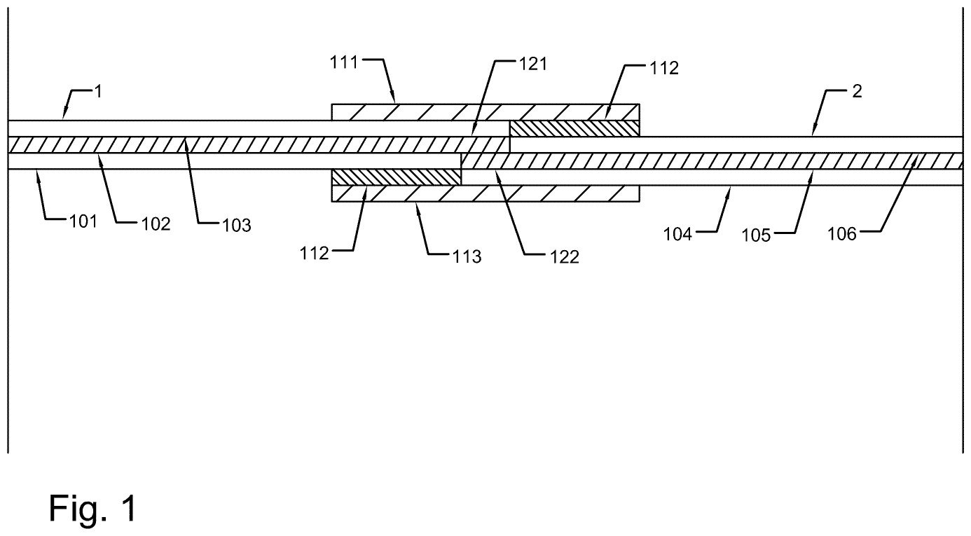

FIG. 1 a longitudinal sectional view of a connection area of two PCB segments

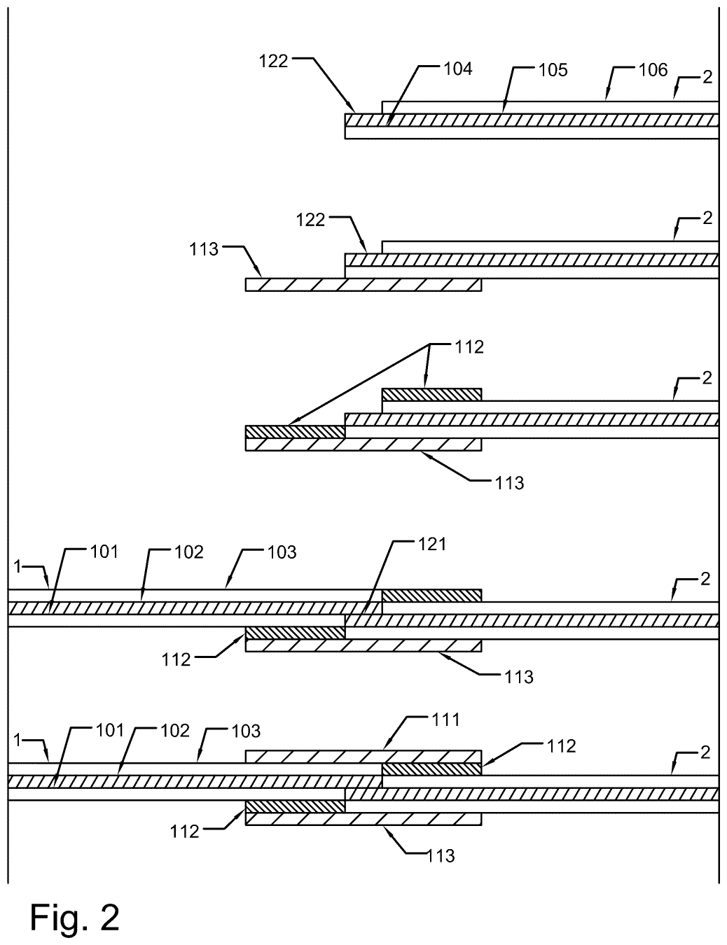

FIG. 2 an exemplary process sequence for manufacturing the connection arrangement

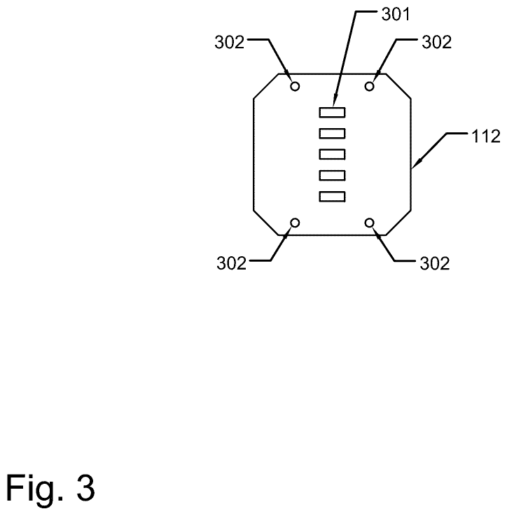

FIG. 3 the thermally activatable layer or film applied or arranged in the connection area

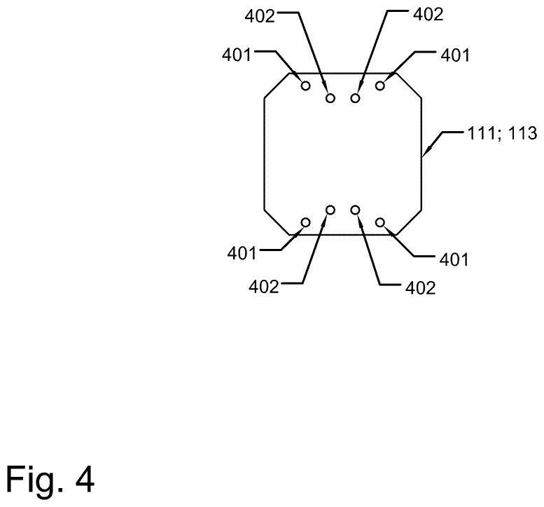

FIG. 4 a basic representation of the reinforcing and positioning layers with positioning holes

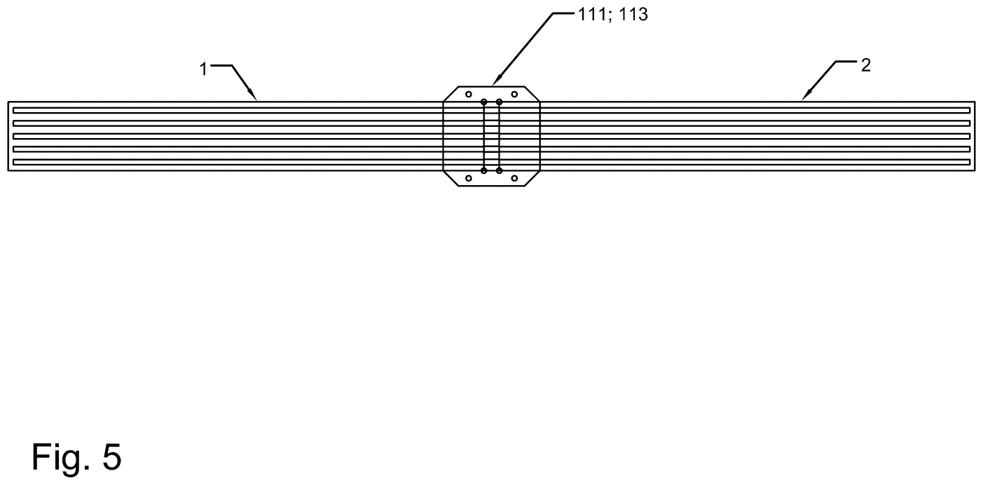

FIG. 5 a top view of two connected circuit board segments with connection area, linear 180°

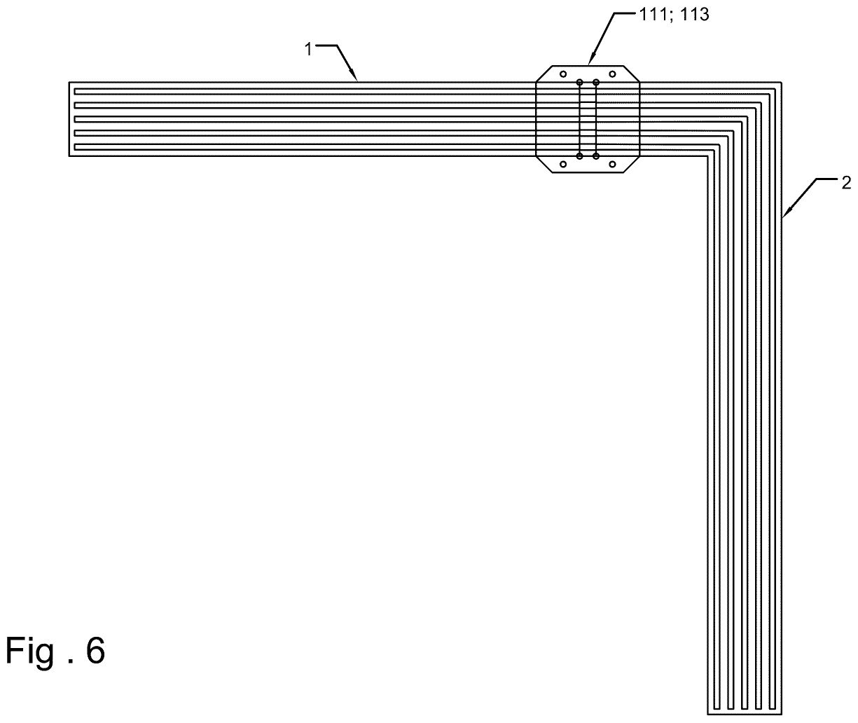

FIG. 6 an illustration similar to that in FIG. 5 but with the connected PCB segments angled at 90°.

The arrangement shown in FIG. 1 forms a PCB composed of two PCB segments (1 and 2).

The individual segments (1 and 2) are connected by laminating the corresponding joints.

The first flexible PCB segment (1) comprises a base insulating layers (103), a first conductive structure (102) comprising a number of conducting tracks, and a cover insulating layer (101).

Furthermore, a second flexible PCB segment (2) comprising a second base insulating layer (104), a second conductive structure (105), and a second cover insulating layer (106) is provided.

In both the first and the second flexible PCB segment (1 and 2), an area of the first cover insulating layer (101) and the second cover insulating layer (106) is exposed in order to obtain a first (121) and second contact surface (122).

These contact surfaces are directly opposite each other to maintain a low-resistance electrical contacting.

The congruence of the contact surfaces (121 and 122) is supported by the fact that a first reinforcing layer (111) is applied to the first base insulating layer (103) and a second reinforcing layer (113) is applied to the second base insulating layer (104) as well as by the fact that positioning holes are provided in both reinforcing layers (111 and 113).

In this respect, we speak of reinforcement and positioning layers 111 and 113.

The actual connection of the existing sandwich structure is achieved by laminating the first flexible PCB segment (1) and the second flexible PCB segment (2) by introducing or applying a sol layer (112) of thermally activatable adhesive around the first (121) and second contact surface (122). The sol layer (112) can also be realized in the form of a film that can be thermally activated.

The insulating base layer and the top insulating layer usually consist of a thermosetting film, in particular a polyimide film.

The sol layer (112) can be a thermally activatable adhesive, in particular an epoxy resin material.

Alternatively, the sol layer (112) can be in the form of a thermosetting film and can be arranged between the first flexible (1) and the second flexible PCB segment (2).

With reference to the sequence shown in FIG. 2, the method according to the invention is explained below.

A PCB segment (2) comprising a base insulating layer (104), a first conductive structure (105), and a cover insulating layer (106) is assumed here. Similarly, a first PCB segment (1) is assumed to consist of a first base insulating layer (103), a first conductive structure (102), and a first cover insulating layer (101). In the area of the first (101) or second cover insulating layer (106), an exposure takes place in order to obtain a first (121) and second contact surface (122) (FIG. 1).

A permanent connection is then created by laminating or gluing between the first PCB segment (1) and the first reinforcing layer (111) or between the second PCB segment (2) and the second reinforcing layer (113).

The aforementioned sol layer (112) is then applied in the joining area of the first PCB segment (1) surrounding the first contact surface (121) but leaving it exposed on the surface side. The second contact surface (122) of the second PCB segment (2) is then positioned over the first contact surface (121), and joining by lamination is carried out by appropriate pressure-temperature treatment in the connection area.

Protrusions of the reinforcing layers (FIGS. 5 and 6) over the contour of the PCB segments can then be removed (e.g., by cutting).

FIG. 3 shows the formation of the sol layer shape of a film structure with recesses (301); these correspond to the shape and position of the contact surface (121 or 122). Furthermore, the structure has positioning holes (302) for positional assignment with respect to the reinforcing and positioning layers provided with similar positioning holes (FIG. 4).

These reinforcing and positioning layers (111 and 113) have an outer (401) and inner group of positioning holes (402).

The inner group of positioning holes (402) is used to assign the positions of the flexible PCB strips to be connected (FIG. 5 or 6). The second, outer group of positioning holes (401) is realized congruently with the positioning holes (302) of the film (112).

Using this method according to the invention, it is now possible to produce flexible PCBs with large expansions in length and width; these exceed the conventional laminating range of known laminating presses. The connection area itself remains highly flexible and has a total material thickness that is only minimally greater than the thickness of the PCB segments.

It is therefore easy to embed such flexible PCBs with a connection area in a multi-pane safety glass or a single-pane film safety glass for a wide range of applications, particularly in the automotive sector.

1. A method for forming an electrical and mechanical connection arrangement of at least two flexible printed circuit boards or flexible printed circuit board segments (1 and 2), whereby these each comprise a composite of a base insulating layers (103 and 104), an electrically conductive structure (102 and 105) comprising conducting tracks, and a cover insulating layer (101 and 106) and the cover insulating layers are exposed or removed in a section of the connection region in order to obtain contact surfaces (121 and 122) comprising:
a first flexible printed circuit board (1) with an exposed contact surface (121) is provided with a first reinforcing and positioning layer (111) and a second flexible printed circuit board (2) with an exposed contact surface (122) is provided with a second reinforcing and positioning layer (113), whereby the surface extent of the first and second reinforcing and positioning layers (111 and 113) extends beyond the respective contact surface (121 and 122) at the rear and forms the connection region, and positioning marks comprising positioning holes (401), are formed in the reinforcing and positioning layers (111 and 113) for position-correct assignment;
a thermally activatable layer or film (112) is applied or arranged in the connection region, thereby leaving the contact surfaces (121 and 122) exposed; and
after the flexible printed circuit boards (1 and 2) have been positioned correctly with their contact surfaces (121 and 122), a joining and laminating step takes place.

2. The method according to claim 1 wherein the lateral protrusions of the reinforcing and positioning layers (111 and 113) are removed.

3. The method according to claim 1 wherein the laminating step comprises a pressure-temperature treatment.

4. The method according to claim 1 wherein the thermally activatable film has positioning marks comprising positioning holes (302) and recesses (301), in the region corresponding to the exposed contact surface (121 and 122).

5. The method according to claim 1 wherein the tolerances with respect to the positional correctness of the layer or film (112) as well as of the first and second reinforcing and positioning layer (111 and 113) are 0.2-0.5 mm.

6. The method according to claim 1 wherein the diameter of formed positioning holes (302 and 401) is 0.5-5.0 mm.

7. The method according to claim 6 wherein the positioning holes are used to vent the joining area during the laminating step.

8. The method according to claim 1 wherein, in order to maintain the flexibility of the connection region, both the reinforcing and positioning layers (111 and 113) and the thermally activatable layer or film (112) comprise a flexible, non-rigid material.

9. The method according to claim 1 wherein the positioning marks or positioning holes in the reinforcing and positioning layers (111 and 113) comprise a first group (402) and a second group (401), the spacing in the first group (402) being matched to the dimensions of the contact surfaces and the width of the flexible printed circuit board strips to be connected and the second group (401) being located inside or outside the area occupied by the flexible printed circuit board strips.

10. The method according to claim 1 wherein the reinforcing and positioning layers (111 and 113) comprise a thermosetting material.

11. The method according to claim 1 wherein the layer or film (112) comprises an epoxy resin material.

12. The method according to claim 1 the flexible printed circuit boards to be connected or the flexible printed circuit board segments (1 and 2) enclose an angle of 0-180°.

13. A flexible printed circuit board being of any length and with a predetermined width, comprising at least two printed circuit board segments (1 and 2) and at least one laminate connection arrangement for electrical and mechanical coupling, wherein the laminate connection arrangement comprises exposed electrical contact surfaces (121 and 122) [,] which lie directly opposite one another and in contact with one another and wherein the laminate connection arrangement comprises at least one reinforcing and positioning layer (111 and 113) on the top and bottom of the electrical contact surfaces (121 and 122).

14. The flexible printed circuit board according to claim 13 wherein the laminate connection arrangement has an additional layer of a thermally activatable material (112) comprising an epoxy resin outside the contact surfaces (121 and 122) but surrounding them.

15. The method according to claim 2 wherein the laminating step comprises a pressure-temperature treatment.

16. The method according to claim 15 wherein the thermally activatable film has positioning marks comprising positioning holes (302) and recesses (301), in the region corresponding to the exposed contact surface (121 and 122).

17. The method according to claim 16 wherein the tolerances with respect to the positional correctness of the layer or film (112) as well as of the first and second reinforcing and positioning layer (111 and 113) are 0.2-0.5 mm.

18. The method according to claim 17 wherein the diameter of formed positioning holes (302 and 401) is 0.5-5.0 mm.

19. The method according to claim 18 wherein the positioning holes are used to vent the joining area during the laminating step.

20. The method according to claim 19 wherein, in order to maintain the flexibility of the connection region, both the reinforcing and positioning layers (111 and 113) and the thermally activatable layer or film (112) comprise a flexible, non-rigid material.
